(19) United States
(12) Patent Application Publication
(10) Pub. No.: US 2004/0262021 A1
(43) Pub. Date: Dec. 30, 2004

(54) Electromagnetic interference shield and method of manufacturing same

(76) Inventor: Charles Leu, Fremont, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 10/867,887

(22) Filed: Jun. 14, 2004

(30) Foreign Application Priority Data
Jun. 13, 2003 (TW) 92116165

(51) Int. Cl. H05K 9/00

(52) U.S. Cl. 174/35 R

(57) ABSTRACT

An electromagnetic interference shield (1) for an electronic device includes a plastic base (12) and a shield layer (10) lapped over the plastic base. Wherein, the shield layer is composed of plastic and metal particles or metal flakes, and the metal particles or metal flakes are substantially tiny with an aspect ratio and a concentration for shielding electromagnetic waves from the electronic device. A method to produce the electromagnetic interference shield includes the steps of:

selecting suitable plastic and metal particles or metal flakes; injection molding a plastic base; and injection molding a shielding layer over the plastic base, thus forming an electromagnetic interference shield.

### BACKGROUND OF THE INVENTION

1. Field of the Invention

The present invention relates to shields for reducing electromagnetic interference from electronic instruments and a method of manufacturing the same, and particularly to an electromagnetic interference shield manufactured using injection molding.

2. Description of Related Art

Electronic devices produce electromagnetic waves which adversely affect performance of other equipments or components. Therefore, an electrically conductive outer shell is needed to shield electromagnetic interference produced from electronic devices. Various methods have been used to shield electronic devices, such as metallic housings and cans fabricated from metal, or plastic with metallic coating by way of plating thereon. However, metal housings are cumbersome, heavy and costly. Moreover, metal housings with intricate shapes are difficult to be fabricated by the conventional metalworking methods. The plating process is costly and complicated.

U.S. Pat. No. 6,207,089 provides an electromagnetic interference shield with a metallic foil cladding a plastic product. A process for manufacturing the same comprises the steps of: coating a first side of a superplastic alloy plate with a coupling agent or hot melt adhesive; placing the superplastic alloy plate in a mold, and superplastically forming the predetermined shape, such that a second side of the superplastic alloy foil is attached to the mold and the first side of the superplastic alloy foil is spaced apart from the mold to form a mold cavity; injecting softened plastic into the mold cavity, such that plastic adheres on the first side of the superplastic alloy foil, thereby an electromagnetic interference shield is formed. However, an adherence is relatively weak between the superplastic alloy foil and the plastic, thus the superplastic alloy foil can be easily peeled off. Moreover, using superplasitc alloy foil increases the cost.

Therefore, an improved electromagnetic interference shield and a method of manufacturing the same is desired which overcomes the disadvantages of the prior art.

### SUMMARY OF THE INVENTION

An object of the present invention is to provide a more dependable electromagnetic interference shield.

Another object of the present invention is to provide a relatively lower-cost method to manufacture the electromagnetic interference shield.

To achieve the above objects, an electromagnetic interference shield for an electronic device comprises a plastic base and a shield layer lapped over the plastic base. Wherein, the shield layer is composed of plastic and metal particles or metal flakes, and the metal particles are substantially tiny with an aspect ratio and a concentration for shielding electromagnetic waves from the electronic device.

The present invention also provides a method to produce the electromagnetic interference shield, which comprises the steps of: selecting suitable plastic and metal particles or metal flakes; injection molding a plastic base; and injection molding a shielding layer over the plastic base, thus forming an electromagnetic interference shield.

Other objects, advantages and novel features of the invention will become more apparent from the following detailed description of a preferred embodiment thereof when taken in conjunction with the accompanying drawings, wherein:

### BRIEF DESCRIPTION OF THE DRAWINGS

FIG. 1 is a perspective view of an electromagnetic interference shield in accordance with a preferred embodiment of the present invention;

FIG. 2 is a cross-sectional view taken along a line II-II of FIG. 1;

FIG. 3 is an enlarged view of a portion III of FIG. 2; and

FIG. 4 is a schematic view of an apparatus for manufacturing the electromagnetic interference shield of FIG. 1.

### DETAILED DESCRIPTION OF THE INVENTION

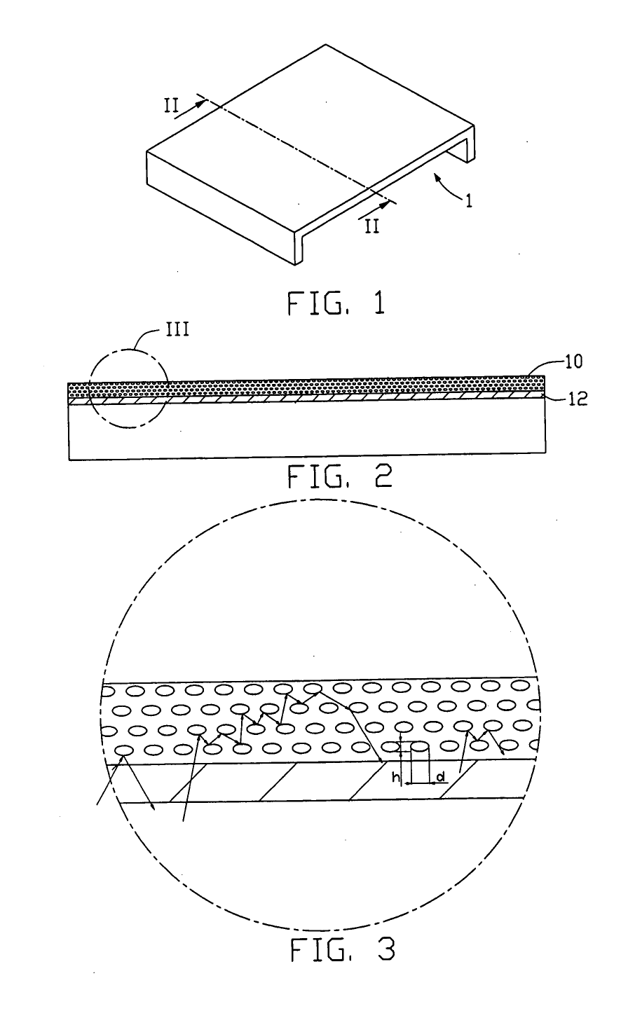

Referring now to the drawings in detail, FIGS. 1 and 2 show an electromagnetic interference shield 1 of the present invention. The electromagnetic interference shield 1 is used as a cover of an electronic device (not shown). The electromagnetic interference shield 1 includes a plastic base 12 and a shielding layer 10 laid over the plastic base 12. Wherein, the shielding layer 10 is composed of plastic and tiny metal particles or metal flakes. The metal particles or metal flakes are finely dispersed in the plastic and tightly embedded therein. The plastic of the base 12 and of the shielding layer 10, which is compatible well with each other, and preferably, being the same plastic, is preferably selected from the group consisting of: polyethylene terephthalate, acrylonitrile-butadiene-styrene, polycarbonate, polyimide, liquid crystal polymer, polyetherimide, polyphenylene sulfide, polysulfone, polystyrene, glycol-modified polyester, polypropylene, or mixtures thereof. The metal, though not limited to, but can be exemplified in particular a metal such as aluminum, copper, steel, zinc, nickel, lead, silver, gold, or mixtures or alloys thereof.

The metal particles or metal flakes in the shielding layer 10 is very tiny. As shown in FIG. 3, a diameter of the article particles is in a range between 0.2 nm to 1.0 mm, while an aspect ratio of metal flakes is in a range between 0.1 μm and 2.0 mm. The shielding layer 10 includes either the metal particles or metal flakes, or both of them therein, which has a predetermined concentration for shielding electromagnetic interference.

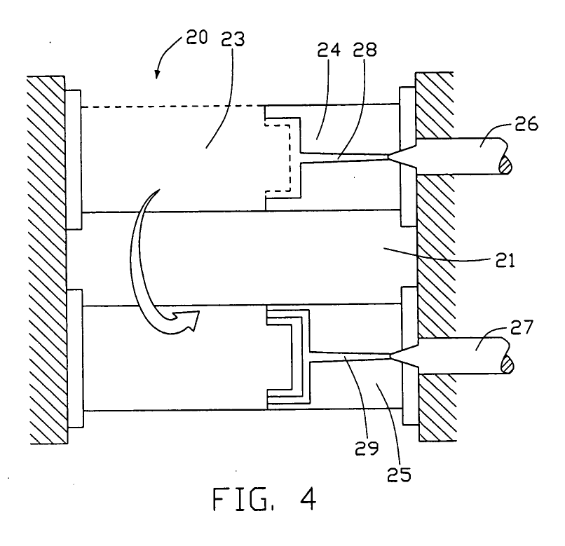

FIG. 4 shows an apparatus 20 for manufacturing the electromagnetic interference shield 1. The apparatus 20 comprises a mold (not labeled) and two feeding hoppers 26, 27. The mold includes one male mold 23 and two female molds 24, 25. Wherein, the male mold 23 is fixed with a rotatable shaft 21 so that it can rotate along with the shaft 21. Each female mold 24, 25 respectively forms an injection port 28, 29 therein, which connects one feeding hopper 26,27 with a cavity defined in a female mold 24, 25. The male mold 23 can be alternately coupled to the female molds 24, 25 when being rotated.

A method for producing the electromagnetic interference shield 1 comprises the steps of: selecting a suitable plastic and metal particles or metal flakes; injection molding the plastic base 12; injection molding the shielding layer 10 over the plastic base 12, and thus forming the electromagnetic interference shield 1.

In the first step, the plastic and metal are selected as described above, then, only the plastic is placed in the hopper 26, but a mixture containing the plastic and metal particles or metal flakes is placed in the hopper 27. The mixture has a predetermined concentration of metal particles or metal flakes which are well blended and dispersed in the plastic. In the second step, the plastic in the hopper 26 is softened and injected into a first cavity (not labeled) defined between the male mold 23 and the first female mold 24 for molding the plastic base 12. After the plastic base 12 is formed, in the third step, the male mold 23 is rotated to be coupled to the second female mold 25 and define a second cavity (not labeled) therebetween, at the same time, the mixture in the hopper 27 is softened and is injected through the injection port 29 into the second cavity, so that the shielding layer 10 is formed on the plastic base 12. Therefore, the electromagnetic interference shield 1 is formed.

Since the plastic of the shield layer 10 and the plastic base 12 is well compatible with each other, the shield layer 10 can tightly adhere to the plastic base 12. Furthermore, when the electromagnetic interference shield 1 is used as a cover of the electronic device, it has good shock-absorption or shock-resistant performance resulting from the plastic base 12.

It is understood that the invention may be embodied in other forms without departing from the spirit thereof. Thus, the present examples and embodiments are to be considered in all respects as illustrative and not restrictive, and the invention is not to be limited to the details given herein.

What is claimed is:

1. An electromagnetic interference shield for an electronic device comprising:
a plastic base; and
a shield layer over the plastic base;
wherein, the shield layer is composed of plastic and a metal material, and the material is substantially tinily sized with an aspect ratio and a concentration for shielding electromagnetic waves from the electronic device.

2. The electromagnetic interference shield as claimed in claim 1, wherein the plastic of the plastic base and of the shield layer is well compatible with each other.

3. The electromagnetic interference shield as claimed in claim 2, wherein the plastic of the plastic base and of the shield layer is selected from the group consisting of polyethylene terephthalate, acrylonitrile-butadiene-styrene, polycarbonate, polyimide, liquid crystal polymer, polyetherimide, polyphenylene sulfide, polysulfone, polystyrene, glycol-modified polyester, and polypropylene.

4. The electromagnetic interference shield as claimed in claim 3, wherein the plastic of the plastic base and of the shield layer is the same plastic.

5. The electromagnetic interference shield as claimed in claim 1, wherein the metal material is aluminum, copper, steel, zinc, nickel, lead, silver, gold, or mixtures or alloys thereof.

6. The electromagnetic interference shield as claimed in claim 1, wherein the aspect ratio of the metal material is in a range between 0.1 μm and 2.0 mm.

7. The electromagnetic interference shield as claimed in claim 6, wherein the metal material is metal particles or metal flakes, or mixtures thereof.

8. A method of manufacturing an electromagnetic interference shield comprising the steps of:
selecting suitable plastic and a metal material;
injection molding a plastic base; and
injection molding a shielding layer over the plastic base, thus forming an electromagnetic interference shield; wherein
the shield layer is composed of plastic and the metal material, and the metal material is in a substantially tiny size with an aspect ratio and a concentration for shielding electromagnetic waves from the electronic device.

9. The method as claimed in claim 7, wherein the plastic of the plastic base and the shield layer is well compatible with each other.

10. The method as claimed in claim 7, wherein the aspect ratio of the metal material is in a range between 0.1 μm and 2.0 mm.

11. The method as claimed in claim 7, wherein the method is carried out in an injection apparatus, the injection apparatus comprises a mold and at least one feeding hopper, and the mold has a male mold and at least one female mold.

12. The method as claimed in claim 10, wherein the mold has two female molds, the male mold is alternatively coupled to the two female molds by way of being fixed with a rotatable shift.

13. The method as claimed in claim 11, wherein there are two feeding hoppers respectively communicating with the two female molds.
